(19) United States
(12) Patent Application Publication
(10) Pub. No.: US 2026/0369523 A1
(43) Pub. Date: Nov. 19, 2026

(54) Focused Ion Beam Device

(71) Applicant: Hitachi High-Tech Corporation, Minato-ku, Tokyo (JP)

(72) Inventor: Toshihiro MOCHIZUKI, Tokyo (JP)

(21) Appl. No.: 19/142,537

(22) PCT Filed: Dec. 27, 2022
(86) PCT No.: PCT/JP2022/048365

§ 371 Date: Jun. 23, 2025

(51) Int. Cl. H01J 37/305; H01J 37/304

(52) U.S. Cl. CPC H01J 37/3056; H01J 37/304; H01J 2237/221; H01J 2237/30466; H01J 2237/31749

(57) ABSTRACT

An object of the present disclosure is to provide a focused ion beam apparatus capable of obtaining information on a cutting cross section before cutting processing performed on a sample is completed. The focused ion beam apparatus according to the disclosure learns in advance a correspondence relationship between a three-dimensional structure of the sample and a processing condition by a learner, and acquires a prediction result of cross-sectional information on the sample from the learner by inputting a position on the three-dimensional structure and the processing condition to the learner (see FIG. 2).

### TECHNICAL FIELD

The present disclosure relates to a focused ion beam apparatus that irradiates a sample with a focused ion beam.

### BACKGROUND ART

A focused ion beam (FIB) apparatus processes a sample by irradiating the sample with a focused ion beam. Further, there is also an apparatus (FIB-SEM: Scanning Electron Microscope) having a function of obtaining an observation image of a sample by detecting secondary particles generated from the sample by irradiating the sample with, for example, an electron beam. For example, the sample is cut by an ion beam, and the observation image of a cutting cross section thereof can be acquired by the electron beam.

The following PTL 1 describes a technique for processing a cross section of a sample using an ion beam. PTL 1 aims to “implement an automatic cross-section processing and observation apparatus that ends cross-section processing and observation when a desired observation target is exposed to a cross section”, and describes a technique of “including a control unit 11 that repeatedly executes a process including slice processing with an ion beam 9 and SIM image acquisition based on secondary electrons emitted from a cross section formed by the processing, in which the control unit 11 divides an observation image into a plurality of areas and ends the process when a change occurs between an image of one area among the plurality of areas and an image of an area corresponding to one area in an observation image of another cross section acquired in the process” (see Abstract).

### CITATION LIST

### Patent Literature

PTL 1: JP2013-200987A

### SUMMARY OF INVENTION

### Technical Problem

In order to obtain an observation image of a cutting cross section of the sample, focused ion beam apparatuses in the related art such as PTL 1 are required to actually perform cutting processing and irradiate the cutting cross section with an electron beam for observation. However, in an actual operation, the cutting cross section may be desired to be observed before the cutting processing is completed. In the related-art focused ion beam apparatuses, such preliminary observation is difficult.

In view of the above problem, an object of the disclosure is to provide a focused ion beam apparatus capable of obtaining information on a cutting cross section before cutting processing performed on a sample is completed.

### Solution to Problem

A focused ion beam apparatus according to the disclosure learns in advance a correspondence relationship between a three-dimensional structure of a sample and a processing condition by a learner, and acquires a prediction result of cross-sectional information on the sample from the learner by inputting a position on the three-dimensional structure and the processing condition to the learner.

### Advantageous Effects of Invention

According to the focused ion beam apparatus of the disclosure, it is possible to obtain information on a cutting cross section before cutting processing performed on the sample is completed. Other problems, configurations, advantages, and the like of the disclosure will become apparent from the following description of embodiments.

### BRIEF DESCRIPTION OF DRAWINGS

FIG. 1 is a configuration diagram of a focused ion beam apparatus 1 according to Embodiment 1.

FIG. 2 is a block diagram illustrating a configuration of a learner 161 included in a control unit 16.

FIG. 3 is a schematic diagram illustrating a method of determining whether cutting processing reaches an end.

FIG. 4 is a diagram illustrating a procedure for updating a cross-sectional image to an image closer to actual cutting processing.

FIG. 5 is a diagram illustrating another method of determining whether cutting processing reaches an end.

### DESCRIPTION OF EMBODIMENTS

### Embodiment 1

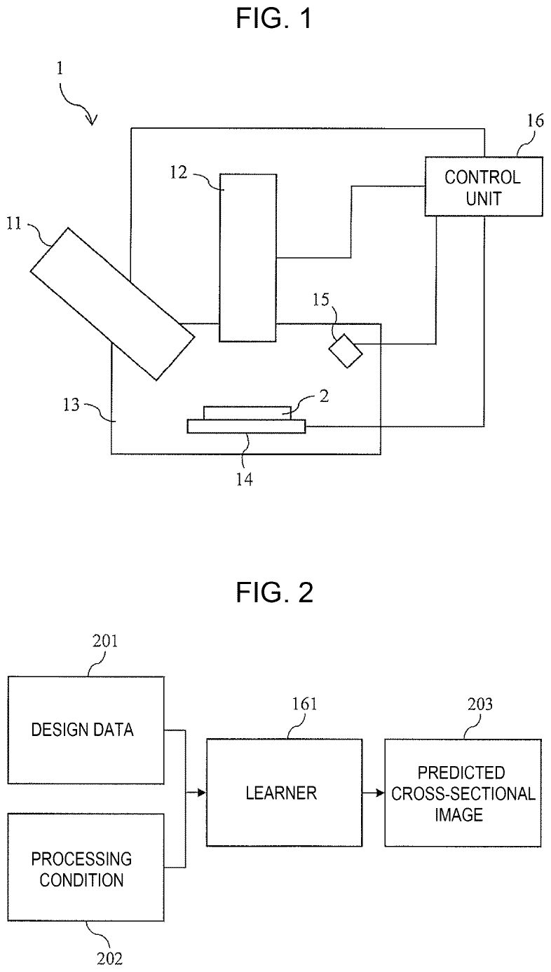

FIG. 1 is a configuration diagram of a focused ion beam apparatus 1 according to Embodiment 1 of the disclosure. The focused ion beam apparatus 1 is an apparatus that processes a sample 2 by irradiating the sample 2 with a focused ion beam. The sample 2 is, for example, a device in which semiconductor elements are three-dimensionally arranged. The focused ion beam apparatus 1 includes an ion beam lens barrel 11 (irradiation unit), an electron beam lens barrel 12 (irradiation unit), a sample chamber 13, a stage 14, a detector 15, and a control unit 16.

The ion beam lens barrel 11 irradiates the sample 2 with the focused ion beam. The electron beam lens barrel 12 irradiates the sample 2 with an electron beam. The sample chamber 13 accommodates the sample 2. The sample 2 can be placed on the stage 14 and can be moved thereon. The detector 15 detects secondary particles generated from the sample 2 by irradiating the sample 2 with the focused ion beam or the electron beam, and outputs a detection signal indicating an intensity of the secondary particles. The control unit 16 controls each unit of the focused ion beam apparatus 1.

FIG. 2 is a block diagram illustrating a configuration of a learner 161 included in the control unit 16. The learner 161 can be constructed by learning in advance, by machine learning, a correspondence relationship between design data 201 describing a three-dimensional structure of the sample 2, a processing condition 202 with respect to the sample 2, and a prediction result (a predicted cross-sectional image 203) for a cross-sectional view of the sample 2 generated according to the processing condition 202.

The design data 201 describes, for each three-dimensional position of the sample 2, a material of the position, a shape or a type of semiconductor elements arranged at the position, and the like. The design data 201 is data describing a design structure of the sample 2 that is created by, for example, a computer aided design (CAD) system.

The processing condition 202 is a condition used to determine how far cutting processing proceeds (that is, a processing speed) when the processing of cutting the sample 2 with the focused ion beam is performed, for example. Examples of the processing condition 202 include the following: a type of gas used when the processing is performed; an acceleration voltage of the focused ion beam; a type of focused ions; a probe current value of the focused ions; an irradiation time length of the focused ion beam at the same position; an inclination correction angle of the focused ion beam (an inclination angle when the stage 14 or the beam is inclined to uniformly apply the beam); and an attachment angle of the sample.

A learning process can be performed as follows. The control unit 16 designates a three-dimensional position on the design data 201, and then acquires the predicted cross-sectional image 203 from the learner 161 by inputting the processing condition 202 to the learner 161. When an erroneous predicted cross-sectional image 203 (for example, a cross-sectional image at another position, and a cross-sectional image having a depth that cannot be reached according to the input processing condition 202) is obtained, a correct predicted cross-sectional image 203 is fed back to the learner 161. By repeating these operations, the learning of the learner 161 can proceed.

The learner 161 includes, for example, a machine learner implemented by a neural network, and trained model data describing a learning result of the machine learner. A learner constructed by another appropriate machine learning method can also be used. These pieces of data can be stored in a storage device included in the control unit 16.

The control unit 16 acquires the predicted cross-sectional image 203 from the learner 161 by designating the three-dimensional position on the design data 201 and then inputting the processing condition 202 to the learner 161 in which the learning is completed. Accordingly, it is possible to obtain a prediction result for a cross-sectional view when it is assumed that the sample 2 is cut, without actually cutting the sample 2. The control unit 16 outputs the prediction result by an appropriate output format such as screen display or data output.

Advantages of obtaining a cross-sectional view without actually performing the cutting processing include the following. For example, depending on skills of an operator, the cutting processing may be performed using a processing condition that is not necessarily appropriate. By inputting the processing condition 202 to the learner 161, it is possible to predict a cutting cross section obtained according to the processing condition 202. In other words, it is possible to predict whether the intended cutting processing can be appropriately performed according to the processing condition 202 without actually performing the processing. When the predicted cross-sectional image 203 is not as expected, the processing condition can be corrected, and an appropriate processing step can be performed again under an appropriate processing condition.

In the present embodiment, instead of or in combination with the design data 201, data describing a three-dimensional structure that is acquired by processing the sample 2 by an apparatus capable of observing the three-dimensional structure of the sample 2 (for example, a charged particle beam apparatus capable of performing three-dimensional observation) may be used in a learning step of the learner 161.

In the present embodiment, the learner 161 may learn other cross-sectional information representing a cross-sectional shape instead of the predicted cross-sectional image 203. For example, it is conceivable to learn a feature of the cross-sectional shape. As an example of the feature, information capable of representing information unique to each cross section, such as a type, the number, a size, a position, and a shape of semiconductor elements arranged on the cross section, can be used.

### Embodiment 2

In Embodiment 1, it has been described that the predicted cross-sectional image 203 is acquired from the learner 161 in which the learning is completed. In addition, it is also possible to update a learning result of the learner 161 using a cross-sectional image acquired by actually performing cutting processing on the sample 2.

First, the cutting processing is performed by irradiating the sample 2 with a focused ion beam. Next, a cut portion is irradiated with an electron beam, and secondary particles are detected by the detector 15. The control unit 16 generates an observation image (cross-sectional image) of the cut portion using a detection signal output from the detector 15. The control unit 16 inputs the generated cross-sectional image and a processing condition during the cutting processing to the learner 161 to relearn a correspondence relationship therebetween. The learner 161 updates the trained model data based on a relearning result.

### Embodiment 3

The predicted cross-sectional image 203 described in Embodiments 1 and 2 can also be used to determine whether cutting processing reaches an end. In particular, when the cutting processing is performed on the fine sample 2, it is common in the related art to determine whether the processing reaches the end subjectively depending on skills of an operator. In Embodiment 3 of the disclosure, a configuration example in which such end determination is automatically performed will be described. A configuration of the focused ion beam apparatus 1 is the same as that according to Embodiments 1 and 2.

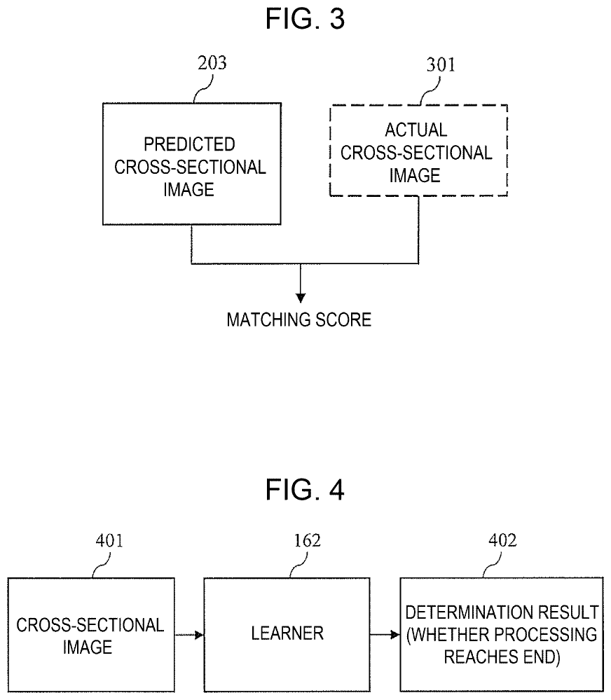

FIG. 3 is a schematic diagram illustrating a method of determining whether the cutting processing reaches the end. As described in Embodiment 1, the control unit 16 can obtain the predicted cross-sectional image 203 from the learner 161. The predicted cross-sectional image 203 is a prediction result of a cross-sectional view obtained by completing the cutting of the sample 2 using a current processing condition. In parallel with this, the control unit 16 acquires an actual cross-sectional image 301 obtained by actually processing the sample 2 by irradiating the sample 2 with an electron beam.

The control unit 16 compares the predicted cross-sectional image 203 with the actual cross-sectional image 301. When the two images match each other, it can be seen that the actual cross-sectional image 301 is a cross-sectional image at a time point when the cutting processing reaches the end, and thus the control unit 16 can determine that the end is reached. The two images can be compared by, for example, acquiring a matching score using an appropriate pattern matching method or the like, and considering that the two images match each other when the score is equal to or greater than a threshold.

FIG. 4 is a diagram illustrating a procedure for updating a cross-sectional image to an image closer to actual cutting processing. A learner 162 receives a cross-sectional image 401 of the sample 2 as an input and outputs an image in which the cross-sectional image 401 is closer to actual cutting processing. Learning of the learner 162 can be performed by repeatedly learning the cross-sectional image 401 and an image obtained by actually performing the cutting processing. Similar to the learner 161, the learner 162 may include any machine learner and trained model data describing a learning result of the machine learner.

The control unit 16 can obtain an image 402 in which a cross-sectional image is closer to the actual cutting processing by inputting the cross-sectional image obtained by actually processing the sample 2 to the learner 162. Accordingly, it is possible to update the predicted cross-sectional image used in the method of determining whether the cutting processing reaches the end in FIG. 3.

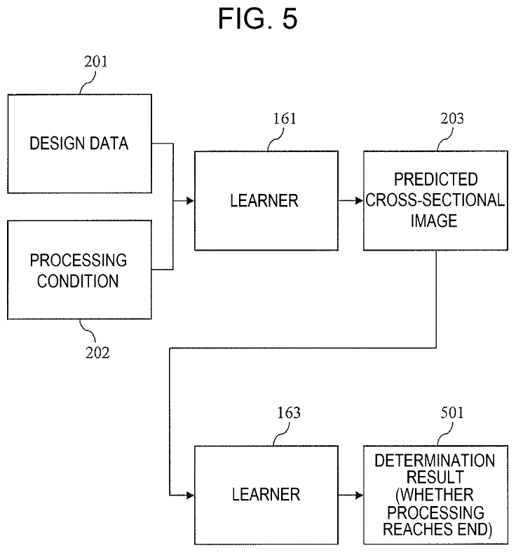

FIG. 5 is a diagram illustrating another method of determining whether cutting processing reaches an end. As the predicted cross-sectional image 203, the learner 161 can output a cross-sectional prediction result when it is assumed that the cutting processing is completed, or can output a cross-sectional prediction result during the cutting. For example, as the processing condition 202, the material of a sample, an etching rate of the material, and an irradiation time length of a focused ion beam at each irradiation position are input to the learner 161, and the predicted cross-sectional image 203 at that time is learned in advance, so that the predicted cross-sectional image 203 during the processing can be obtained from the learner 161.

By inputting the predicted cross-sectional image 203 during the processing to a learner 163 having the same configuration as the learner 162, the control unit 16 can obtain a determination result 501 of whether the cutting processing reaches the end from the learner 163. The learner 163 may have the same configuration as the learner 162, or may receive, instead of the predicted cross-sectional image 203, cross-sectional information (for example, a feature of a cross-sectional view) equivalent to the predicted cross-sectional image 203.

According to a determination method in FIG. 5, when there is a processing abnormality, the abnormality can be detected before the processing reaches the end by checking a processing progress during the processing.

### Embodiment 4

In the above embodiments, the learner 161 may perform the learning step in consideration of the processing speed of the sample 2. For example, the processing speed varies depending on a relationship between an etching rate of the material of the sample 2 described in the design data 201, an acceleration voltage designated by the processing condition 202, and an ion beam current, and the like. By performing the learning step after designating an irradiation time length of a focused ion beam at the same irradiation position as the processing condition 202, it is possible to predict how far the processing proceeds based on the processing speed. Accordingly, the predicted cross-sectional image 203 at any time point during the processing can be obtained based on the processing speed of the sample 2.

The processing speed of the sample 2 may vary depending on a beam profile (beam shape) of the focused ion beam. By designating the beam profile as the processing condition 202 and then performing the learning step, the learner 161 can predict how far the processing proceeds based on the processing speed according to the beam profile.

### Regarding Modifications of Disclosure

The disclosure is not limited to the above embodiments and includes various modifications. For example, the above embodiments are described in detail to facilitate understanding of the disclosure, and it is not necessary to include all the configurations described above. A part according to one embodiment can be replaced with a configuration according to another embodiment. A configuration according to another embodiment can be added to a configuration according to one embodiment. A part of a configuration according to each embodiment may be added to, deleted from, or replaced with a part of a configuration according to another embodiment.

In the above embodiments, the control unit 16 may be implemented by hardware such as a circuit device having a function of the control unit 16, or may be implemented by a calculation device such as a central processing unit (CPU) executing software having a function thereof.

In the above embodiments, irradiation with an electron beam has been described as a method for observing the sample 2, and other charged particle beams may be used as long as an observation image can be obtained. For example, the observation image may be acquired by irradiation with an ion beam different from the ion beam for processing.

### REFERENCE SIGNS LIST

1: focused ion beam apparatus
11: ion beam lens barrel
12: electron beam lens barrel
13: sample chamber
14: stage
15: detector
16: control unit
161: learner

1. A focused ion beam apparatus for irradiating a sample with a focused ion beam, the focused ion beam apparatus comprising:
an irradiation unit configured to process the sample by irradiating the sample with the focused ion beam; and
a control unit configured to control the irradiation unit, wherein
the control unit is configured to acquire a prediction result of cross-sectional information representing a cross-sectional shape of the sample by inputting a position on a three-dimensional structure of the sample to a learner and output the prediction result, the learner being trained by machine learning using the three-dimensional structure of the sample and a processing condition as input, and
the control unit acquires the prediction result at the position from the learner by inputting the position on the three-dimensional structure and the processing condition to the learner.

2. The focused ion beam apparatus according to claim 1, wherein
the learner is configured to perform the machine learning using three-dimensional data, which describes the three-dimensional structure, and the processing condition,
the three-dimensional data describes at least one of a material at a three-dimensional position of the sample or an element arranged at the three-dimensional position of the sample,
the learner is configured to learn at least one of the material at the three-dimensional position of the sample or the element by being trained by the machine learning using the three-dimensional data and the processing condition as input, and
the control unit acquires, from the learner, at least one of the material at the three-dimensional position of the sample or the element that is learned by the learner as the prediction result.

3. The focused ion beam apparatus according to claim 1, wherein
the irradiation unit irradiates the sample with a charged particle beam used to acquire a cross-sectional image of the sample,
the control unit acquires the cross-sectional image by detecting a secondary particle generated from the sample by irradiating the sample with the charged particle beam, and
the control unit updates a learning result with the learner by causing the learner to learn the acquired cross-sectional image and the processing condition again.

4. The focused ion beam apparatus according to claim 1, wherein
the irradiation unit irradiates the sample with a charged particle beam used to acquire a cross-sectional image of the sample,
the control unit acquires the cross-sectional image by detecting a secondary particle generated from the sample by irradiating the sample with the charged particle beam, and
the control unit determines a progress of the processing by comparing the cross-sectional image with the prediction result.

5. The focused ion beam apparatus according to claim 4, wherein
the control unit acquires the prediction result at a time point when the processing is completed, and
the control unit controls the irradiation unit to end the processing when determining that the acquired prediction result matches the cross-sectional image.

6. The focused ion beam apparatus according to claim 5, wherein
the control unit compares the cross-sectional image with the prediction result by performing pattern matching between the cross-sectional image and the prediction result, and
the control unit determines that the acquired prediction result matches the cross-sectional image when a matching score in the pattern matching is equal to or greater than a threshold.

7. The focused ion beam apparatus according to claim 5, wherein
the control unit determines whether the processing ends by inputting the cross-sectional image to a second learner that learns in advance a correspondence relationship between the cross-sectional image and whether the processing ends by the machine learning.

8. The focused ion beam apparatus according to claim 5, wherein
the control unit determines whether the processing ends by inputting the prediction result to a third learner that learns in advance a correspondence relationship between the prediction result and whether the processing ends by the machine learning.

9. The focused ion beam apparatus according to claim 1, wherein
the learner learns in advance a correspondence relationship among a material of the sample, the processing condition, and a processing speed of the sample by the machine learning, and
the control unit acquires the cross-sectional information reflecting the processing speed from the learner by inputting the material and the processing condition to the learner.

10. The focused ion beam apparatus according to claim 1, wherein
the learner learns in advance a correspondence relationship between a beam shape of the focused ion beam and a processing speed of the sample by the machine learning, and
the control unit acquires the cross-sectional information reflecting the processing speed from the learner by inputting the beam shape to the learner.

11. The focused ion beam apparatus according to claim 2, wherein
the three-dimensional data is design data describing a result of designing a structure of the sample.

12. The focused ion beam apparatus according to claim 2, wherein
the three-dimensional data is data acquired by a charged particle beam apparatus irradiating the sample or another sample having the same structure as the sample with a charged particle beam and analyzing the three-dimensional structure.

13. The focused ion beam apparatus according to claim 1, wherein
the processing condition is at least one of a type of gas used when the processing is performed, an acceleration voltage of the focused ion beam, a type of the focused ion, a probe current of the focused ion beam, an irradiation time length of the focused ion beam at the same position, an inclination correction angle of the focused ion beam, or an attachment angle of the sample.
